(19) United States
(12) Patent Application Publication
(10) Pub. No.: US 2024/0087925 A1
(43) Pub. Date: Mar. 14, 2024

(54) INFORMATION PROCESSING APPARATUS AND PARAMETER CONTROL METHOD

(71) Applicant: Tokyo Electron Limited, Tokyo (JP)

(72) Inventors: Youngtai KANG, Yamanashi (JP); Yuichi TAKENAGA, Yamanashi (JP); Kiwamu ITO, Yamanashi (JP); Rui IKEDA, Iwate (JP); Ken OKOSHI, Yamanashi (JP)

(21) Appl. No.: 18/243,059

(22) Filed: Sep. 6, 2023

(30) Foreign Application Priority Data
Sep. 12, 2022 (JP) 2022-144788

(51) Int. Cl. H01L 21/67

(52) U.S. Cl. CPC H01L 21/67253; H01L 21/67248

(57) ABSTRACT

An information processing apparatus includes a data acquisition unit, a simulation execution unit, and an optimization unit. The data acquisition unit acquires execution result data including an execution result of the substrate processing based on a process parameter including a pressure in the substrate processing apparatus and including sensor data of the pressure in the substrate processing apparatus. The simulation execution unit inputs the execution result data into a simulation model pre-stored in a storage to calculate a pressure in the substrate processing apparatus that is predicted to approach a target value for a substrate processing result. The optimization unit calculates a predicted value of the substrate processing result based on the process parameter including the calculated pressure.

### CROSS-REFERENCE TO RELATED APPLICATIONS

The present application is based on and claims priority from Japanese Patent Application No. 2022-144788, filed on Sep. 12, 2022, with the Japan Patent Office, the disclosure of which is incorporated herein in its entirety by reference.

### TECHNICAL FIELD

The present disclosure relates to an information processing apparatus, a parameter control method, and a storage medium.

### BACKGROUND

Techniques for measuring the temperature inside a processing chamber used in the semiconductor manufacturing apparatus have been developed. The measurement results are used to control the process conditions of a substrate processing executed in the processing chamber (see, e.g., Japanese Patent Laid-Open Publication No. 2004-172409).

### SUMMARY

According to an aspect of the present disclosure, an information processing apparatus includes a data acquisition unit, a simulation execution unit, and an optimization unit. The data acquisition unit acquires execution result data, which includes an execution result of a substrate processing based on a process parameter including a pressure in a substrate processing apparatus and includes sensor data of the pressure in the substrate processing apparatus. The simulation execution unit inputs the execution result data into a simulation model pre-stored in a storage unit, and calculate a pressure value in the substrate processing apparatus that is predicted to approach a target value for the substrate processing result. The optimization unit calculates a predicted value of the substrate processing result based on the process parameter that includes the calculated pressure value.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a schematic cross-sectional view illustrating an exemplary substrate processing system according to an embodiment.

FIG. 2 is a schematic cross-sectional view illustrating exemplary substrate processing apparatus according to an embodiment.

FIG. 3 is a diagram illustrating an exemplary film formation method using the ALD technique according to an embodiment.

FIG. 4 is a diagram illustrating an exemplary functional configuration of an information processing apparatus according to an embodiment.

FIG. 5 illustrates experimental results that represent the correlation between the opening degree of an APC control valve and the in-plane uniformity of the film thickness according to an embodiment.

FIG. 6 illustrates experimental results that represent the correlation between the opening degree of the APC control valve and the in-plane uniformity of the film thickness according to an embodiment.

FIG. 7 illustrates experimental results that represent the correlation between the opening degree of the APC control valve and the in-plane uniformity and inter-plane uniformity of the film thickness according to an embodiment.

FIGS. 8A and 8B are diagrams illustrating the presence or absence of rotation of a boat and the film thickness distribution.

FIG. 9 is a diagram illustrating the intended use of the opening degree of the APC control valve.

FIG. 10 is a flowchart illustrating an exemplary substrate processing according to an embodiment.

FIG. 11 is a flowchart illustrating exemplary parameter control processing according to an embodiment.

FIG. 12 is a diagram illustrating exemplary effects achieved by the parameter control processing according to an embodiment.

FIG. 13 is a diagram illustrating an exemplary hardware configuration of the information processing apparatus according to an embodiment.

### DETAILED DESCRIPTION

In the following detailed description, reference is made to the accompanying drawings, which form a part thereof. The illustrative embodiments described in the detailed description, drawings, and claims are not meant to be limiting. Other embodiments may be utilized, and other changes may be made without departing from the spirit or scope of the subject matter presented here.

Embodiments for carrying out the present disclosure are described below with reference to the drawings. The same reference numerals are used to indicate the same components across the drawings, omitting repetitive descriptions in some cases.

<Substrate Processing System>

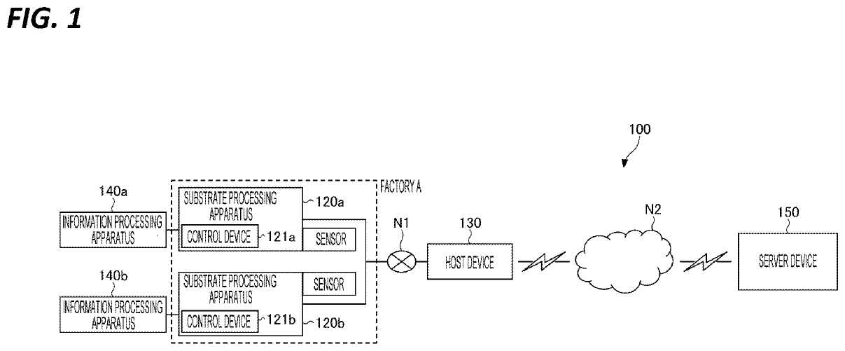

An exemplary configuration of a substrate processing system according to an embodiment is now described. FIG. 1 illustrates an exemplary configuration of the substrate processing system 100 according to an embodiment. As illustrated in FIG. 1, the substrate processing system 100 includes, in a factory A, substrate processing apparatuses 120a and 120b and their respective corresponding control devices 121a and 121b. The substrate processing apparatus 120a and the control device 121a are connected by wire or wirelessly. The substrate processing apparatus 120b and the control device 121b are connected by wire or wirelessly.

The control device 121a may be provided inside the substrate processing apparatus 120a. The control device 121b may be provided outside the substrate processing apparatus 120b. Further, the substrate processing system 100 may include other substrate processing apparatus and control devices within the same factory A or other factories.

The substrate processing apparatus 120a and 120b are connected to a host device 130 via a network N1. The substrate processing apparatus 120a performs a substrate processing under the control of the control device 121a in accordance with an instruction from the host device 130. The substrate processing apparatus 120b performs a substrate processing under the control of the control device 121b in accordance with an instruction from the host device 130. The host device 130 is linked to a server device 150 via a network N2, such as the Internet. Throughout the following description, the substrate processing apparatus 120a and 120b are also collectively referred to as “substrate processing apparatus 120.” In addition, the control devices 121a and 121b are also collectively referred to as “control device 121.”

The substrate processing apparatus 120 is equipped with a sensor such as a pressure sensor or temperature sensor. The sensor data obtained from the sensor that detects the state or condition of the substrate processing apparatus 120 is individually managed for each substrate processing apparatus 120. The obtained multiple sensor data items are accumulated in each of the substrate processing apparatuses 120 and administrated by the control device 121. As described later, a display unit that presents a “predicted value of a substrate processing result” may be a display unit of the control device 121, a display unit of the substrate processing apparatus 120, a display unit of the information processing apparatus 140, or a display unit of other apparatuses.

The control device 121 processes a computer-executable instruction that directs the substrate processing apparatus 120 to perform a substrate processing, including film formation and etching. The control device 121 may control individual components of the substrate processing apparatus 120 to perform various substrate processings. In one embodiment, the control device 121 may include a processor, a storage unit, and a communication interface. The control device 121 is implemented as, for example, a computer. The processor may read a program from the storage unit and execute the read program, carrying out various control operations. This program may be stored in a storage unit in advance or acquired through a suitable medium as necessary. Once acquired, the program is stored in the storage unit and then loaded from the storage unit for execution by the processor. The program includes a parameter control program. Examples of such a medium may include various computer-readable storage media or a communication line connected to a communication interface. The processor may be a central processing unit (CPU). The storage unit may include random-access memory (RAM), read-only memory (ROM), a hard disk drive (HDD), a solid-state drive (SSD), or a combination thereof. The communication interface may communicate with the substrate processing apparatus 120 over a communication line such as a local area network (LAN).

The substrate processing apparatus 120a is connected to the information processing apparatus 140a. The information processing apparatus 140a acquires an execution result obtained from the substrate processing executed by the substrate processing apparatus 120a (hereinafter also referred to as a “process result”), a process parameter used for execution, and multiple sensor data items managed by the substrate processing apparatus 120a. The substrate processing apparatus 120b is connected to the information processing apparatus 140b. The information processing apparatus 140b acquires an execution result of substrate processing executed by the substrate processing apparatus 120b, a process parameter used for execution, and multiple sensor data items managed by the substrate processing apparatus 120b. The information processing apparatuses 140a and 140b are also collectively referred to as the information processing apparatus 140 in the following description. The substrate processing apparatus 120 and the information processing apparatus 140 may be connected on a one-to-one basis, or a plurality of substrate processing apparatuses 120 may be connected to a single information processing apparatus 140 on a many-to-one basis. Rather than providing the information processing apparatus 140, the host device 130 or the server device 150 may also serve as the information processing apparatus 140.

<Substrate Processing Apparatus>

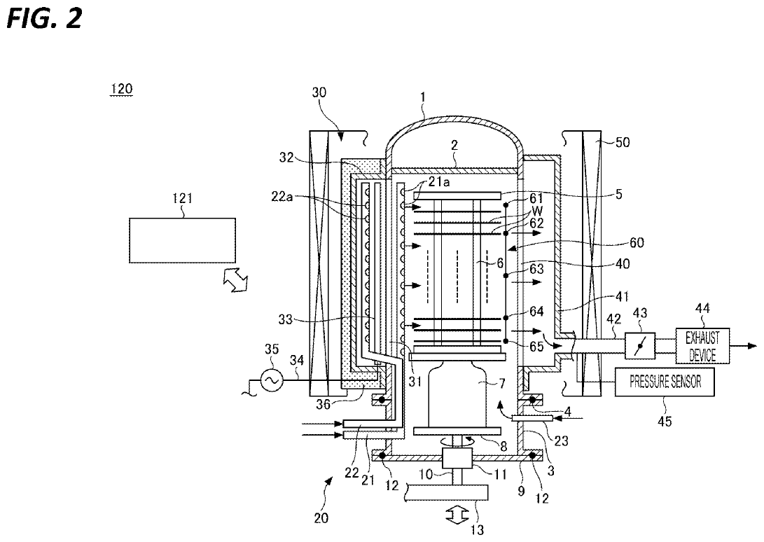

Next, an example of the substrate processing apparatus 120 according to an embodiment will be described with reference to FIG. 2. FIG. 2 illustrates a schematic cross-sectional view illustrating an example of the substrate processing apparatus according to an embodiment. In FIG. 2, descriptions will be made on a plasma processing apparatus that processes a substrate using plasma, as an example of the substrate processing apparatus 120. The substrate processing apparatus 120 includes a processing chamber 1. The processing chamber 1 is cylindrical in shape and has a ceiling with an open bottom end. The processing chamber 1 is entirely made of quartz. The processing chamber 1 is provided with a ceiling plate 2 made of quartz in the vicinity of the upper end thereof. The ceiling plate 2 is sealed in the lower region. The processing chamber 1 is provided with an open lower end to which a manifold 3 is connected using a sealing member 4, such as an O-ring. The manifold 3 is cylindrically molded and made of metal.

The manifold 3 supports the lower end of the processing chamber 1. From the lower side of the manifold 3, a boat 5 on which a plurality (e.g., 25 to 150) of substrates W is placed in multiple stages is inserted into the processing chamber 1. Thus, the processing chamber 1 accommodates the multiple substrates W in a substantial horizontal orientation with vertical intervals. The boat 5 is made of quartz. The substrate W may be, for example, a semiconductor wafer. The boat 5 is an exemplary substrate holder capable of holding the multiple substrates W placed in multiple stages. The insertion of the boat 5 into the processing chamber 1 of the substrate processing apparatus 120 enables simultaneous processing of the multiple substrates W.

The boat 5 is placed on a table 8 via a heat-reserving cylinder 7 made of quartz. The table 8 is supported on a rotary shaft 10 penetrating through a metal (stainless steel) lid 9 that is responsible for opening and closing the lower end opening of the manifold 3.

A magnetic fluid seal 11 is installed in the penetrating portion of the rotary shaft 10 to hermetically seal and rotatably support the rotary shaft 10. To keep the inside of the processing chamber 1 airtight, a sealing member 12 is provided between the peripheral portion of the lid 9 and the lower end of the manifold 3.

The rotary shaft 10 is affixed to the tip of an arm 13, which is supported by an elevating mechanism (not illustrated), such as a boat elevator. Both the boat 5 and the lid 9 move cohesively in an upward and downward direction and are removable from the inside of the processing chamber 1. The table 8 may be fixed to the side of the lid 9 to process the substrate W without rotating the boat 5.

The substrate processing apparatus 120 has a gas supply unit 20 configured to deliver predetermined gas, such as processing gas or purge gas, to the processing chamber 1.

The gas supply unit 20 has gas supply pipes 21 to 23. The gas supply pipes 21 and 22 are made of quartz. The gas supply pipes 21 and 22 penetrate the side wall of the manifold 3 inward, bend upward, and extend vertically. The gas supply pipes 21 and 22 have a plurality of gas holes 21a and 22a spaced at predetermined intervals in their vertical portions over a vertical length corresponding to the substrate support range of the boat 5. The gas holes 21a and 22a each discharge gas horizontally. The gas supply pipe 23 is made of quartz and is a relatively shorter quartz pipe penetrating through the side wall of the manifold 3. In the illustrated example, two gas supply pipes 21 and one each of the gas supply pipes 22 and 23 are provided.

The gas supply pipe 21 has a vertical portion that is provided inside the processing chamber 1. The gas supply pipe 21 is supplied with a silicon (Si)-containing gas (raw material gas), such as silane (SiH₄) gas, from a raw material gas source through a gas pipe. The gas pipe is provided with a flow controller and an on-off valve. This configuration allows the supply of the raw material gas from the raw material gas source into the processing chamber 1 at a predetermined flow rate through both the gas pipe and the gas supply pipe 21.

The gas supply pipe 22 has a vertical portion provided in a plasma generation space, which will be described later. The gas supply pipe 22 is supplied with a reactant gas, such as ammonia (NH 3) gas from a reactant gas source through a gas pipe. The gas pipe is provided with a flow controller and an on-off valve. This configuration enables the supply of the reactant gas from the reactant gas source through both the gas pipe and the gas supply pipe 22 to the plasma generation space at a predetermined flow rate. In the plasma generation space, the supplied reactant gas is converted into plasma, and the resulting plasma is then supplied into the processing chamber 1.

The gas supply pipe 23 is supplied with a purge gas from a purge gas source through a gas pipe. The gas pipe is provided with a flow controller and an on-off valve. This configuration enables the supply of the purge gas from the purge gas source to the processing chamber 1 at a predetermined flow rate through both the gas pipe and the gas supply pipe 23. Examples of the purge gas include inert gases such as nitrogen (N 2) or argon (Ar). The purge gas may be supplied from at least one of the gas supply pipes 21 to 23.

The processing chamber 1 has a plasma generation mechanism 30 formed on part of the side wall thereof. The plasma generation mechanism 30 converts the reactant gas into plasma to generate active species for nitridation. The plasma generation mechanism 30 has several components, including a plasma partition wall 32, a pair of plasma electrodes 33, a power supply line 34, an RF power supply 35, and an insulation protection cover 36.

The plasma partition wall 32 is hermetically welded to the outer wall of the processing chamber 1. The plasma partition wall 32 is made of quartz. The plasma partition wall 32 has a concave cross-section and covers an opening 31 formed in the side wall of the processing chamber 1. The opening 31 is elongated vertically to cover all the substrates W supported by the boat 5 in the vertical direction. The plasma generation space is the inner space, which is defined by the plasma partition wall 32 and communicates with the inside of the processing chamber 1. The gas supply pipe 22 is arranged within the inner space. The gas supply pipe 21 is provided at a position near the substrate W along the inner wall of the processing chamber 1 outside the plasma generation space.

The pair of plasma electrodes 33 (only one of which is illustrated in FIG. 2) are elongated in shape and arranged to face each other on the outer surfaces of both side walls of the plasma partition wall 32 in the vertical direction. The plasma electrodes 33 have their respective lower ends connected to the power supply line 34.

The power supply line 34 is electrically connected to the plasma electrodes 33 and the RF power supply 35. In the illustrated example, the power supply line 34 has one end connected to the lower end of the shorter side of each of the plasma electrodes 33 and the other end connected to the RF power supply 35.

The RF power supply 35 is connected to the lower end of each of the plasma electrodes 33 via the power supply line 34 and supplies the pair of plasma electrodes 33 with RF power of, for example, 13.56 MHz. This configuration enables the application of RF power to the plasma generation space defined by the plasma partition wall 32. The reactant gas released from the gas supply pipe 22 is converted into plasma within the plasma generation space where the RF power is applied. The resulting active species for nitridation are supplied to the interior of the processing chamber 1 through the opening 31.

The insulating protective cover 36 is attached to the exterior of the plasma partition wall 32, effectively covering it. Inside the insulation protection cover 36, a refrigerant passage (not illustrated) is provided to cool the plasma electrode 33 by flowing the cooled N₂ gas or a similar refrigerant through the refrigerant passage. To cover the plasma electrode 33, a shield (not illustrated) may be provided between the plasma electrode 33 and the insulating protective cover 36. The shield is composed of a good conductor with high conductivity, typically metal, and is grounded.

The side wall portion of the processing chamber 1 that faces the opening 31 is provided with an exhaust port 40, allowing the evacuation of the interior of the processing chamber 1. The exhaust port 40 is elongated vertically to align with the boat 5. To cover the exhaust port 40, an exhaust port cover member 41 with a U-shaped cross-section is attached to a portion of the processing chamber 1 that corresponds to the exhaust port 40. The exhaust port cover member 41 extends upward along the side wall of the processing chamber 1. To exhaust the processing chamber 1 through the exhaust port 40, an exhaust pipe 42 is connected to the lower portion of the exhaust port cover member 41. The exhaust pipe 42 is connected to a pressure control valve 43 (hereinafter referred to as “APC valve”) used to control the pressure in the processing chamber 1. The exhaust pipe 42 is also connected to an exhaust device 44, which includes a vacuum pump and other related components. The exhaust device 44 evacuates the interior of the processing chamber 1 through the exhaust pipe 42. The exhaust pipe 42 is attached with a pressure sensor 45, detecting the pressure inside the exhaust pipe 42. The pressure detected by the pressure sensor 45, that is, the opening degree of the APC valve 43 is used to control the pressure inside the processing chamber 1.

There is provided a heating unit 50 around the processing chamber 1. The heating unit 50 is cylindrical in shape and includes a heater that allows heating both the processing chamber 1 and the substrates W located inside the processing chamber 1. The heater is provided on the side wall of the processing chamber 1, enabling individual temperature control in multiple zones in the height direction of the processing chamber 1.

The processing chamber 1 has a temperature sensor 60 provided measure the temperature inside the processing chamber 1. The temperature sensor 60 has, for example, a plurality of temperature measuring units 61 to 65 provided at different positions in the height direction corresponding to multiple zones. The temperature measuring units 61 to 65 are provided to correspond to zones “TOP,” “C-T,” “CTR,” “C-B,” and “BTM,” respectively. The plurality of temperature measuring units 61 to 65 may be implemented as a configuration like a thermocouple or resistance temperature detector. The temperature sensor 60 transmits temperature values detected by the plurality of temperature measuring units 61 to 65 to the control device 121.

<Film Formation Method>

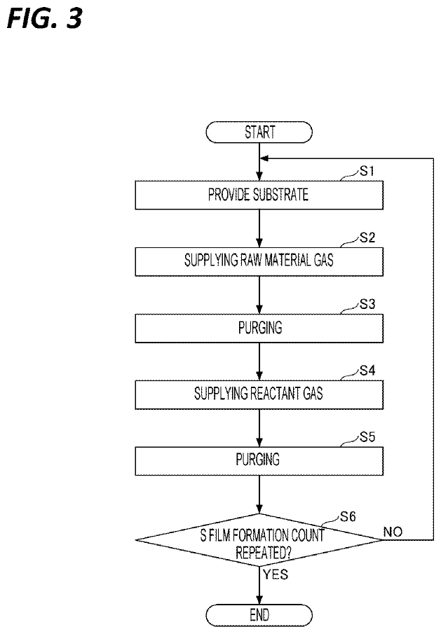

An exemplary film formation method according to an embodiment is briefly described below with reference to FIG. 3. The film formation method according to an embodiment is controlled by the control device 121 and executed by the substrate processing apparatus 120. A method of forming a SiN film is now briefly described as an exemplary film formation method. The substrate processing apparatus 120 uses an atomic layer deposition (ALD) technique for film formation. However, the substrate processing apparatus 120 may perform film formation of a given film using a chemical vapor deposition (CVD) technique. Moreover, the film to be deposited using ALD or CVD technique is not limited solely to the SiN film.

Upon beginning film formation processing illustrated in FIG. 3, in step S1, the control device 121 causes the insertion of the boat 5 into the processing chamber 1, providing a substrate. Then, in step S2, the control device 121 initiates the delivery of a silicon-containing gas (e.g., silane gas) as an example of a raw material gas from the gas supply pipe 21 into the processing chamber 1 (supplying a raw material gas). This leads to the absorption of the silicon-containing gas onto the surface of the substrate W.

Subsequently, in step S3, the control device 121 causes the atmosphere in the processing chamber 1 to replace the silicon-containing gas with N₂ gas (purging). In the present embodiment, the delivery of N₂ gas from the gas supply pipe 23 into the processing chamber 1 while evacuating the inside of the processing chamber 1 by the exhaust device 44 allows the atmosphere in the processing chamber 1 to be replaced with N₂ gas from the silicon-containing gas. This purging may be omitted if necessary.

Then, in step S4, the substrate W is exposed to plasma produced from ammonia gas. In the present embodiment, the delivery of ammonia gas from the gas supply pipe 22 into the processing chamber 1 and the application of RF power from the RF power source 35 to the pair of plasma electrodes 33 allow the ammonia gas to be converted into plasma, generating active species for nitridation to supply them to the substrate W (nitriding). This results in the reaction of the silicon-containing gas absorbed onto the substrate W reacts with the ammonia gas to form a SiN film.

Subsequently, in step S5, the atmosphere in the processing chamber 1 is replaced from ammonia gas to N₂ gas (purging). In the present embodiment, the delivery of N₂ gas from the gas supply pipe 23 into the processing chamber 1 while evacuating the inside of the processing chamber 1 by the exhaust device 44 allows the atmosphere in the processing chamber 1 to be replaced with N₂ gas from the ammonia gas. This purging may be omitted if necessary.

Then, in step S6, it is determined whether the cycle from the first step to the fourth step (referred to as one cycle or one round) has reached the predetermined film formation count. The film formation count is determined depending on a factor such as the thickness of the SiN film to be formed. When the number of cycles has yet to reach the film formation count in the fifth step, the processing from the first to fourth steps is repeated. When the number of cycles reaches the film formation count, this processing ends. This results in the formation of the SiN film with an intended film thickness on the substrate W.

<Functional Configuration of Information Processing Apparatus>

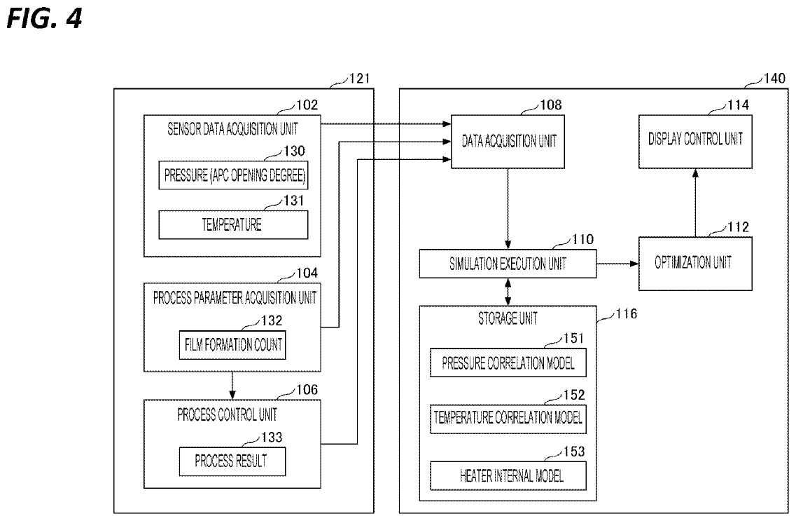

An exemplary functional configuration of the information processing apparatus 140 according to an embodiment is now described with reference to FIG. 4. FIG. 4 illustrates an exemplary functional configuration of the information processing apparatus 140 according to an embodiment. The information processing apparatus 140 has a storage unit 116 with a parameter control program installed. The execution of this parameter control program allows the information processing apparatus 140 to function as a data acquisition unit 108, a simulation execution unit 110, an optimization unit 112, and a display control unit 114, as illustrated in FIG. 4.

The data acquisition unit 108 continuously acquires specific data from a plurality of data managed by the control device 121 and stores it in the storage unit 116. Examples of the data managed by the control device 121 include sensor data indicating the state or condition of the substrate processing apparatus 120 that is detected by a sensor attached to the substrate processing apparatus 120. The sensor data may be an internal pressure (opening degree of the APC valve 43), an internal temperature (detection value of the temperature sensor 60), and other sensed values of the substrate processing apparatus, which are detected by a sensor attached to the substrate processing apparatus 120. The sensor data is acquired by the sensor data acquisition unit 102 of the control device 121 and transmitted to the information processing apparatus 140. Examples of the sensor data include various data such as temperature, pressure, gas species, gas flow rate, RF power, an opening degree of the APC valve, luminous intensity, each stage use time in the process, and temperature increase and/or decrease rate. Examples of the sensor include the temperature sensor 60, the pressure sensor 45, a film thickness sensor, a mass flow controller, and a plasma emission monitor. The sensor data includes a substrate processing execution result (process result) indicating the execution result of substrate processing, such as in-plane uniformity of the film thickness of the substrate W, inter-plane uniformity of the film thickness of a plurality of substrates, and the film formation quantity. These results are obtained from a film thickness sensor (not illustrated) during the substrate processing procedure following the recipe.

The control device 121 has a process parameter acquisition unit 104 that sets a process parameter, including the opening degree of the APC valve 43 used to control the pressure inside the substrate processing apparatus 120 and the temperature (heater temperature) of the heating unit 50 used to control the temperature inside the substrate processing apparatus 120. The control device 121 has a process control unit 106 that controls a substrate processing following the procedure indicated by the recipe based on the set process parameter. This leads to the processing of the multiple substrates W inserted into the substrate processing apparatus 120.

The process control unit 106 transmits execution result data, which includes the substrate processing execution result (process result), the opening degree of the APC valve 43, and the heater temperature of the heating unit 50, to the data acquisition unit 108. In one embodiment, data regarding the in-plane thickness of one or multiple substrates measured by the film thickness sensor is transmitted as an example of the substrate processing execution result. The execution result data may include a film formation time. In the case of film formation using the ALD technique, the execution result data may include the film formation count, exemplifying the film formation time.

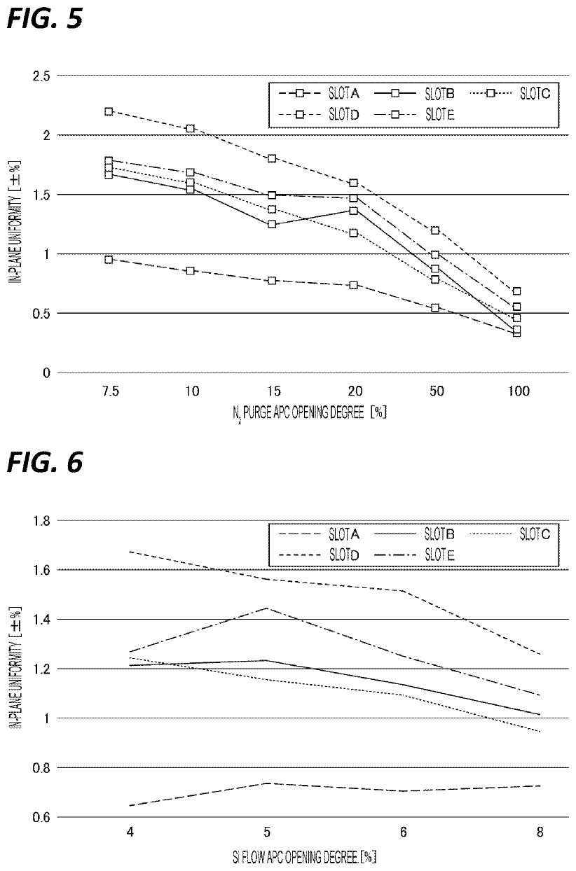

The simulation execution unit 110 inputs the execution result data into a pressure correlation model 151, which is pre-stored in the storage unit 116, and calculates the opening degree of the APC valve 43 that is predicted to approach a target value for the substrate processing result. The pressure correlation model 151 is an example of a first model representing the correlation between the opening degree of the APC valve 43 and the substrate processing execution result. The substrate processing execution result may involve the in-plane uniformity for the thickness of the film formed on the substrate (see FIG. 5). The substrate processing execution result is not limited to the in-plane uniformity, but may include the inter-plane uniformity of the film thickness of multiple substrates and the film formation quantity as the substrate processing execution result.

FIGS. 5 and 6 illustrate exemplary graphs of experimental results representing an example of the correlation between the opening degree of the APC valve 43 and the in-plane uniformity of the film thickness according to an embodiment. The data in the graphs of FIGS. 5 and 6 were obtained by varying the opening degree of the APC valve 43 at values of 7.5%, 10%, 15%, 20%, 50%, and 100%, as denoted on the horizontal axis. In this case, the substrate processing apparatus 120 underwent the purge process without altering other process parameters (process conditions). As illustrated in FIG. 5, N₂ gas was used as the purge gas in the purge process. In FIG. 6, a silicon (Si)-containing gas was supplied.

In the graphs, slots A, B, C, D, and E are designated for respective corresponding zones divided into “TOP,” “C-T,” “CTR,” “C-B,” and “BTM” in order from the top of the boat 5 out of approximately 25 to 150 slots used for placing the substrates W provided in the boat 5. The film thickness was measured radially on the substrate W with a diameter of 300 mm placed in the slots A, B, C, D, and E. The film thickness was measured by using a film thickness sensor. The vertical axis represents the in-plane uniformity of the film thickness in percentage, obtained from the measurements taken in the radial direction of each slot.

The verification was performed on how the in-plane uniformity of the film thickness of the substrate W represented on the vertical axis varies with the opening degree of the APC valve 43 represented on the horizontal axis. The results show, for the N₂ gas purging, that increasing the opening degree of the APC valve 43 led to improvement in the in-plane uniformity of the film thickness in all slots, and the most significant enhancement occurred when the opening degree of the APC valve 43 was set to 100%, which is illustrated in the example of FIG. 5.

In the case of purging with a silicon (Si)-containing gas, the example of FIG. 6 illustrates that increasing the opening degree of the APC valve 43 led to improvement in the in-plane uniformity of some slots. In the example presented in FIG. 6, setting the APC opening degree to 100% generally enhanced the in-plane uniformity of the film thickness, with the exception of the slot A. The in-plane uniformity of the film thickness falls within the acceptable range if it is 1% to 1.5% or less. Thus, it may be concluded that the in-plane uniformity of the film thickness has been enhanced.

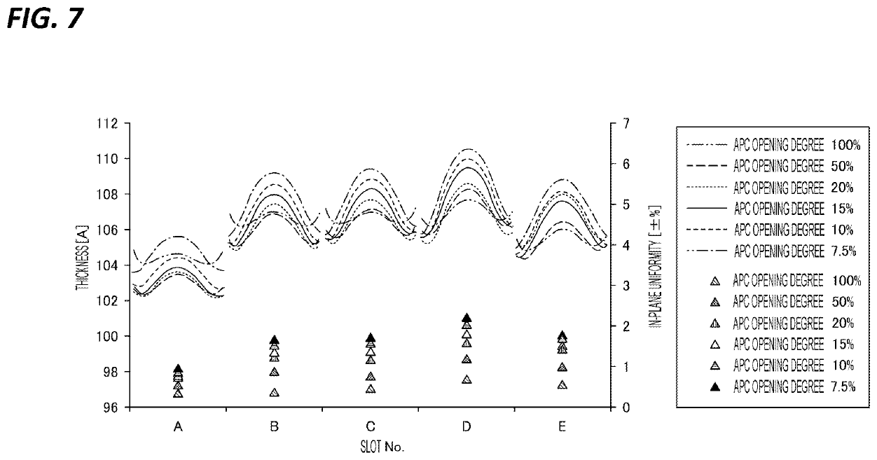

FIG. 7 illustrates a graph of experimental results that represent an exemplary correlation between the opening degree of the APC valve 43 and the in-plane uniformity and inter-plane uniformity of the film thickness, according to an embodiment. The data presented in the graph of FIG. 7 were obtained by varying the opening degree of the APC valve 43 at values of 7.5%, 10%, 15%, 20%, 50%, and 100%. In this case, the processing chamber 1 of the substrate processing apparatus 120 underwent a purge process following the procedure indicated by the same recipe, with no alterations made to other process parameters. In the purge process illustrated in FIG. 5, N₂ gas was used as the purge gas, while other conditions remained without alteration.

In FIG. 7, the horizontal axis represents the slot number, the left vertical axis represents the film thickness, and the right vertical axis indicates the in-plane uniformity of the film thickness. In this figure, the value denoted by a symbol A indicates the in-plane uniformity of the film thickness on the substrate W in respective slots A to E in the case of varying the opening degree of the APC valve 43 at values of 7.5%, 10%, 15%, 20%, 50%, and 100%.

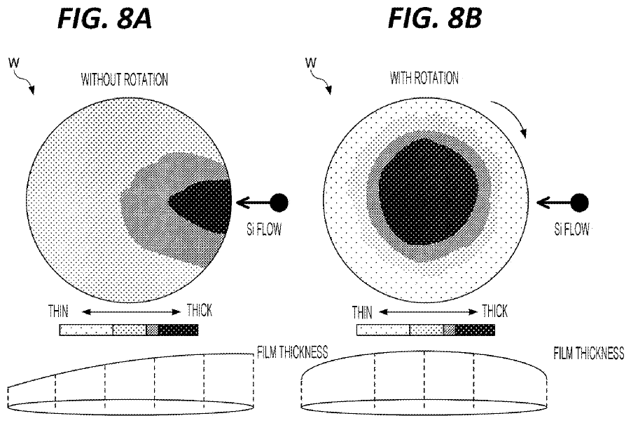

FIGS. 8A and 8B are diagrams illustrating the presence or absence of rotation of the boat 5 and its relationship with the film thickness. FIG. 8A illustrates the film thickness on the substrate W in the case where the boat 5 is not rotating and the silicon (Si)-containing gas is supplied from the right side. The film thickness exhibits a gradient, being thickest at the right end of the substrate W where the silicon (Si)-containing gas is supplied, gradually thinning towards the left, and reaching its thinnest point at the left end of the substrate W.

Meanwhile, FIG. 8B illustrates the film thickness on the substrate W in the case where the boat 5 is rotating and the silicon (Si)-containing gas is supplied from the right side. The film thickness is thin at the right end of the substrate W to which the silicon (Si)-containing gas is supplied and in the other peripheral portions, but as it progresses towards the center, it gradually thickens, forming a structure resembling a mountain. Thus, the rotation of the boat 5 results in the film thickening at the center of the substrate W while thinning at the periphery, leading to enhancement in the in-plane uniformity of the film.

The mountain-like shape of the film thickness illustrated in FIG. 7 indicates the film thickness in the radial direction of the substrate W in each slot in the case of rotating the boat 5 and varying the opening degree of the APC valve 43 at values of 7.5%, 10%, 15%, 20%, 50%, and 100%. The left end of each mountain-like shape indicates the film thickness of the substrate W around −150 mm, the center of each mountain-like shape indicates the film thickness of the substrate W at the center, and the right end of each mountain-like shape indicates the film thickness of the substrate W around +150 mm. In all the substrates W, the film thickness exhibited the most significant increase at the center.

Referring to the in-plane uniformity value indicated by the symbol A in each slot, it was observed that the in-plane uniformity values vary depending on the opening degree of the APC valve 43 at each slot position. Thus, it was found that controlling the opening degree of the APC valve 43 allows for the adjustment of the in-plane uniformity of the film thickness. Furthermore, it was found that the inter-surface uniformity values of the substrate vary depending on the opening degree of the APC valve 43 at each slot position by referring to the mountain-like shape of the film thickness. It was found that controlling the opening degree of the APC valve 43 enables the adjustment of the inter-plane uniformity of the film thickness at each slot position. In other words, it was found that controlling the opening degree of the APC valve 43 affects not only the in-plane uniformity of the film thickness but also the inter-plane uniformity of the film thickness. From these findings, the pressure correlation model 151 is created to facilitate in-plane and inter-plane adjustment by controlling the opening degree of the APC valve 43. Specifically, the parameter control according to the present embodiment collectively optimizes the in-plane and inter-plane uniformity of the process execution result by controlling the opening degree of the APC valve 43.

From the aforementioned findings, the pressure correlation model 151 is created, including information regarding the correlation between the opening degree of the APC valve 43 and the in-plane uniformity and/or inter-plane uniformity of the film thickness on the substrate. The pressure correlation model 151 exemplifies the first model that represents the correlation between the opening degree of the pressure control valve and the substrate processing execution result. In this context, the “substrate processing execution result” refers to the in-plane uniformity and/or the inter-surface uniformity of the process execution result, such as film thickness.

The simulation execution unit 110 inputs the execution result data including the opening degree of the APC valve 43 into the pressure correlation model 151 to calculate the opening degree of the APC valve 43 predicted to approach a target value for the substrate processing result. The target value for the substrate processing result includes, but is not limited to, at least one of a target value for the in-plane uniformity of film thickness, a target value for the inter-plane uniformity of film thickness, and the film thickness. In the case of film formation processing using the CVD technique, the simulation execution unit 110 inputs the execution result data including the pressure of the substrate processing apparatus 120 into the pressure correlation model 151 to calculate the pressure of the substrate processing apparatus 120 that is predicted to approach the target value for the substrate processing result.

The correlation between the opening degree of the APC valve 43 and the in-plane uniformity of the film thickness as illustrated in FIGS. 5 and 6 is derived from experiments to create the pressure correlation model 151, which is pre-stored in the storage unit 116. The simulation execution unit 110 inputs the substrate processing execution result and the opening degree of the APC valve 43 into the pressure correlation model 151 to calculate the optimized opening degree of the APC valve 43. The optimization unit 112 optimizes the process parameter based on the calculated opening degree of the APC valve 43 and calculates a predicted value of the substrate processing result based on the optimized process parameter. This optimization of the process parameter based on the opening degree of the APC valve 43 involves updating the opening degree of the APC valve 43 among the process parameters.

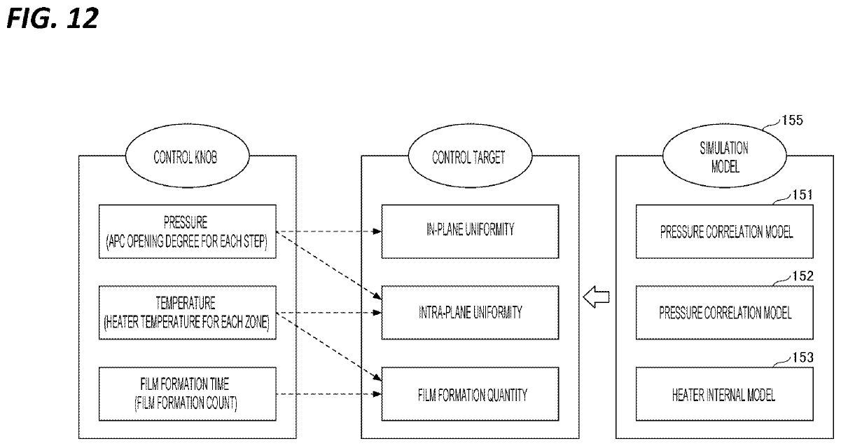

The pressure correlation model 151 is included in a simulation model 155 (see FIG. 12). Furthermore, the simulation model 155 includes a temperature correlation model 152, which is a correlation model between the substrate processing execution result and the temperature of the heating unit 50 that controls the temperature of the substrate processing apparatus 120 (hereinafter also referred to as heater temperature). Additionally, the simulation model 155 also includes a heater internal model 153.

Further, as illustrated in FIGS. 5 and 6, changing the gas species led to a variation in the correlation between the opening degree of the APC valve 43 and the in-plane uniformity of the film thickness on the substrate. The opening degree of the APC valve 43 refers to the control of the gas exhaust rate to control the pressure inside the processing chamber 1. Notably, during the film formation processing using the ALD technique, steps S2 to S5 illustrated in FIG. 3 are switched in a shorter period of time, such as several seconds. For this reason, the sensor data of the pressure inside the substrate processing apparatus detected by the pressure sensor 45 will represent a slightly delayed past pressure value relative to the current pressure value inside the processing chamber 1.

The gas exhaust rate is controlled by using the opening degree of the APC valve 43. In other words, changing the opening degree of the APC valve 43 refers to a variation in the pressure in the processing chamber 1, and optimizing the opening degree of the APC valve 43 leads to the optimization of the pressure in the processing chamber 1. Thus, especially in the film formation processing using the ALD technique, controlling the pressure in the processing chamber 1 using the opening degree of the APC valve 43 enables more accurate control of the pressure in the processing chamber 1.

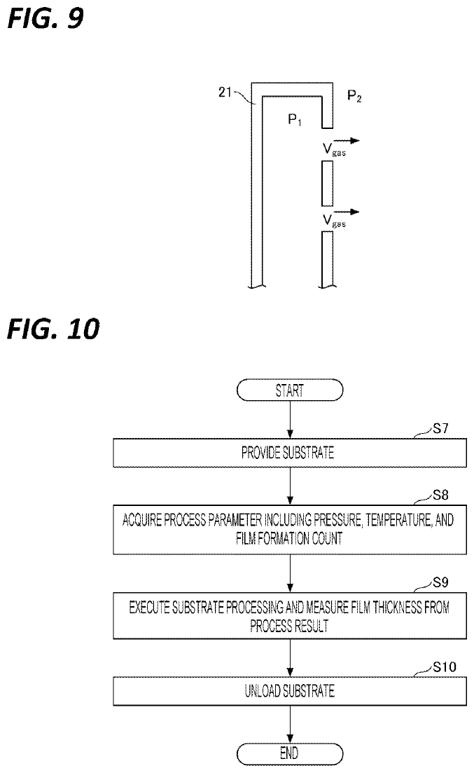

FIG. 9 illustrates how the difference (P2−P1) between a pressure P1 inside the gas supply pipe 21 and a pressure P2 inside the processing chamber 1 is used to adjust the gas velocity V_{gas}. In the film formation method using the ALD technique, steps S2 to S5 in FIG. 3 demand instantaneous switching, which prompts the adjustment of the opening degree of the APC valve 43. Thus, the difference (P2−P1) between the pressure P1 and the pressure P2 is adjustable. Adjusting the difference (P2−P1) between the pressure P1 and the pressure P2 changes the amount of gas injected into the processing chamber 1, leading to the variation in the pressure inside the processing chamber 1. In one example, setting the pressure inside the processing chamber 1 to 1 Torr allows for adjusting the opening degree of the APC valve 43 to achieve a pressure of 1 Torr inside the processing chamber. The film formation method using the CVD technique controls the set pressure value within the processing chamber.

It is more appropriate to use the pressure correlation model 151 created for each step at multiple steps that are set in the recipe (e.g., steps S2 to S5 in FIG. 3) to adjust the APC opening degree based on the pressure correlation model 151 for each step. This approach ensures precise control of the pressure in the processing chamber 1 and enhances the in-plane uniformity or other film thickness attributes, leading to a more precise formation of a target film thickness profile. Examples of the target value for the film thickness profile involve setting the in-plane uniformity of the film thickness to 1% to 1.5% or less. The target value for the film thickness profile represents an instance of the target value for the substrate processing result, and other examples of the target value for the substrate processing result involve setting the inter-surface uniformity of the film thickness to a predetermined threshold value or less and setting the film thickness to a predetermined thickness or more. In other words, the target value for the substrate processing result may be at least one or a combination of two or more of the in-plane uniformity, the inter-plane uniformity, and the film thickness of the film formation process execution result. Furthermore, the process execution result is not limited to film formation, and may be an etching execution result obtained by executing etching. In such cases, the target value for the substrate processing result may be at least one or a combination of two or more of uniformity of critical dimension (CD) value, uniformity of verticality of etching, and uniformity of etching depth of the etching process execution result.

The display control unit 114 causes the predicted process result to be displayed on a display unit. The display unit may be a display unit of the substrate processing apparatus 120, a display unit of the control device 121, or a display unit of the information processing apparatus 140.

The optimization unit 112 may update the process parameter to be used in the substrate processing apparatus 120 with the optimized process parameter in accordance with an instruction from the user for the displayed process result (predicted value of the substrate processing result).

The optimization unit 112 may automatically determine whether or not to update the process parameter to be used in the substrate processing apparatus 120 with the optimized process parameter based on the displayed process result.

<Substrate Processing>

Referring to FIG. 10, a substrate processing according to an embodiment will be described below. FIG. 10 is a flowchart illustrating an exemplary substrate processing according to an embodiment. This processing is controlled by the control device 121 and executed by the substrate processing apparatus 120.

Upon beginning this processing, in step S7, the process control unit 106 of the control device 121 causes the boat 5 to be inserted into the processing chamber 1 of the substrate processing apparatus 120 and provides a plurality of substrates W. Then, in step S8, the process parameter acquisition unit 104 acquires a process parameter including pressure (opening degree of the APC valve 43), temperature, and film formation count. Upon receiving an update notification from an information processing apparatus, which will be described later, the process parameter acquisition unit 104 updates the process parameter to be used with the acquired process parameter.

Subsequently, in step S9, the process control unit 106 executes substrate processing in the processing chamber 1 of the substrate processing apparatus 120 and measures the film thickness from the process result to acquire film thickness data. Then, in step S10, the process control unit 106 unloads the substrate W and ends this substrate processing.

<Parameter Control Processing>

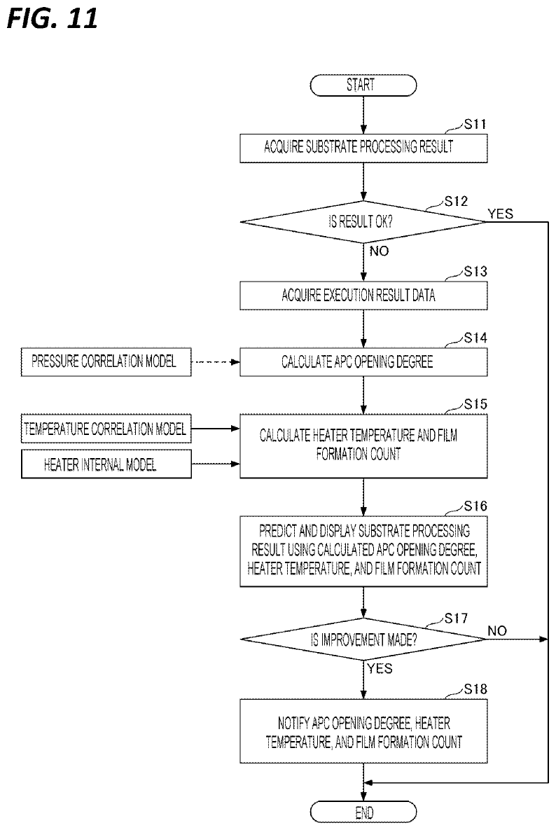

Subsequently, parameter control processing according to an embodiment will be described below with reference to FIG. 11. FIG. 11 is a flowchart illustrating exemplary parameter control processing according to an embodiment. This parameter control processing is executed by the information processing apparatus 140 each time the substrate processing apparatus 120 executes a substrate processing.

Upon beginning this processing, in step S11, the data acquisition unit 108 of the information processing apparatus 140 acquires the substrate processing execution result (process result). The process result may be the in-plane uniformity of the film thickness, the inter-plane uniformity of the film thickness, a combination thereof, or any other criteria for evaluating the effectiveness of the process.

In step S12, the data acquisition unit 108 determines whether the process result falls within the allowable range (OK) or not. When the data acquisition unit 108 determines that the process result is OK, the processing ends. Meanwhile, when the data acquisition unit 108 determines that the process result is out of the allowable range (NG), the data acquisition unit 108 acquires the execution result data from the control device 121 in step S13. The execution result data includes film thickness data, which is the execution result of the substrate processing, the opening degree of the APC valve 43, the heater temperature of the heating unit 50, and the film formation count.

Subsequently, in step S14, the simulation execution unit 110 inputs the execution result data into the pressure correlation model 151 pre-stored in the storage unit 116. In an embodiment, the film thickness data and the opening degree of the APC valve 43 are input to the pressure correlation model 151. The simulation execution unit 110 uses the pressure correlation model 151 to calculate the opening degree of the APC valve 43 that is predicted to approach the target value for the substrate processing result (e.g., the target value for the in-plane uniformity of the film thickness).

Subsequently, in step S15, the simulation execution unit 110 inputs the execution result data into the temperature correlation model 152 pre-stored in the storage unit 116. The simulation execution unit 110 may also input the execution result data into the temperature correlation model 152 and the heater internal model 153, which are pre-stored in the storage unit 116. In an embodiment, the film thickness data, the sensor data of temperature, and the film formation count are input to the temperature correlation model 152. The simulation execution unit 110 calculates the heater temperature of the heating unit 50 and the film formation count predicted to approach the target value for the substrate processing result (e.g., the target value for inter-plane uniformity of film thickness).

Subsequently, in step S16, the optimization unit 112 executes a simulation of the substrate processing based on the process parameter including the calculated opening degree of the APC valve 43, heater temperature, and film formation count to calculate a predicted value of the process result. In one example, the heater temperature may be the temperature of the heater of each zone in the heating unit 50. The display control unit 114 causes the predicted value of the process result to be displayed on the display unit. In step S17, the optimization unit 112 determines whether the process result is improved by the predicted value of the process result using the optimized parameter in accordance with the instruction from the user (operator). When the optimization unit 112 determines that the improvement is made, then in step S18, the opening degree of the APC valve 43, the heater temperature (heater temperature of each zone of the heating unit 50), and the film formation count, which are calculated, are notified to the control device 121 or other user terminals, and this processing ends. When the optimization unit 112 determines that the improvement is not made, the optimization unit 112 ends this processing and stands by the following process result.

<Exemplary Effects>

The effects achieved from the parameter control processing of FIG. 11 will be described below with reference to FIG. 12. FIG. 12 is a diagram illustrating exemplary effects of parameter control processing according to an embodiment.

Conventionally, the in-plane uniformity of the film thickness and the inter-plane uniformity of the film thickness were separately optimized using different control methods. In one example, the heater temperature of each zone is optimized in the inter-plane uniformity of film thickness, while the in-plane uniformity of film thickness is optimized by using a control method that adjusts the heater temperature of each zone of the heating unit 50, raising and lowering it.

The parameter control processing according to the present embodiment enables the information processing apparatus 140 to execute the parameter control program and use the simulation model 155 to optimize the process parameter. In this case, the control knobs are pressure (opening degree of the APC valve 43), the temperature (heater temperature for each zone), and the film formation time (film formation count). Further, the targets to be controlled are the in-plane uniformity of the film thickness, the inter-plane uniformity of the film thickness, and the film formation quantity. This leads to the calculation of the optimized opening degree of the APC valve 43, heater temperature, and film formation count. Thus, it becomes possible to collectively adjust both the in-plane uniformity of the film thickness and the inter-plane uniformity of the film thickness, which are the targets to be controlled.

In particular, inputting the process result and the opening degree of the APC valve 43 into the pressure correlation model 151 makes it possible to calculate the opening degree of the APC valve 43 (the pressure inside the processing chamber 1), improving the in-plane and inter-plane uniformity of the film thickness.

As described above, the information processing apparatus 140 according to the present embodiment or the parameter control program according to the present embodiment enables the improvement of the uniformity of the substrate processing result.

The substrate processing apparatus presented in the present disclosure is also applicable to various types of apparatuses, including a single-wafer apparatus that processes substrates individually, a batch apparatus that processes multiple substrates simultaneously, and a semi-batch apparatus. The substrate processing apparatus presented in the present disclosure is capable of performing various substrate processing tasks including film formation and etching.

The semiconductor manufacturing apparatus presented in the present disclosure is not limited to an apparatus that processes a substrate using plasma. It may also be an apparatus that processes a substrate without using plasma.

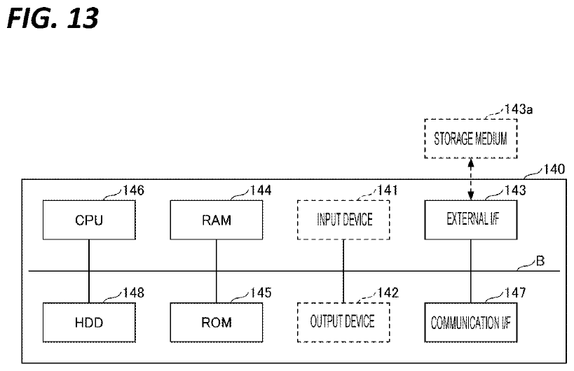

FIG. 13 is a diagram illustrating an exemplary hardware configuration of the information processing apparatus 140 according to an embodiment. The information processing apparatus 140 illustrated in FIG. 13 includes an input device 141, an output device 142, an external interface (I/F) 143, random-access memory (RAM) 144, read-only memory (ROM) 145, a central processing unit (CPU) 146, a communication I/F 147, a hard disk drive (HDD) 148, and other devices, which are interconnected via a bus B. The input device 141 and the output device 142 are connectable for use when necessary.

The input device 141 may be a keyboard, mouse, touch panel, or other similar devices, enabling the operator or users to enter various operation signals. The output device 142 may be a display or other similar devices and displays the results of processing by the information processing apparatus 140. The communication I/F 147 is an interface that facilitates the connection of the information processing apparatus 140 to a network. The HDD 148 is an exemplary non-volatile storage device that stores programs and data.

The external I/F 143 is an interface that enables connection with an external device. The external I/F 143 allows the information processing apparatus 140 to read from and/or write in a recording medium 143a, such as a secure digital (SD) memory card. The ROM 145 is an exemplary non-volatile semiconductor memory (storage device) that stores programs and data. The RAM 144 is an exemplary volatile semiconductor memory (storage device) that temporarily holds programs or data.

The CPU 146 is a processing and computing unit that loads programs or data from storage devices such as the ROM 145 and HDD 148 onto the RAM 144 and executes processing tasks, implementing the overall control and functionality of the information processing apparatus 140.

According to an aspect, the uniformity of the substrate processing result may be enhanced.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. An information processing apparatus comprising:
a data acquisition circuitry configured to acquire execution result data including an execution result of a substrate processing based on a process parameter including a pressure in a substrate processing apparatus, and including sensor data of the pressure in the substrate processing apparatus;
a simulation execution circuitry configured to input the execution result data into a simulation model stored in a storage, and calculate a pressure in the substrate processing apparatus that is predicted to approach a target value for a substrate processing result; and
an optimization circuitry configured to calculate a predicted value of the substrate processing result based on the process parameter including the calculated pressure.

2. The information processing apparatus according to claim 1, wherein the simulation execution circuitry calculates an opening degree of a pressure control valve arranged in an exhaust pipe connected to the substrate processing apparatus as the pressure in the substrate processing apparatus.

3. The information processing apparatus according to claim 2, wherein the data acquisition circuitry acquires the execution result data including the execution result of the substrate processing, the opening degree of the pressure control valve, and sensor data of a temperature in the substrate processing apparatus,
the simulation execution circuitry inputs the execution result of the substrate processing and the opening degree of the pressure control valve into a first model of the simulation model, and calculates the opening degree of the pressure control valve that is predicted to approach the target value for the substrate processing result,
the simulation execution circuitry inputs the execution result of the substrate processing and the sensor data of the temperature into a second model of the simulation model, and calculates a temperature of a heater of the substrate processing apparatus that is predicted to approach the target value for the substrate processing result,
the optimization circuitry optimizes the process parameter based on the calculated opening degree of the pressure control valve and the calculated temperature of the heater,
the first model represents a correlation between the opening degree of the pressure control valve and the execution result of the substrate processing, and
the second model represents a correlation between the temperature of the heater and the execution result of the substrate processing.

4. The information processing apparatus according to claim 3, wherein the data acquisition circuitry further acquires the execution result data including a film formation time,
the simulation execution circuitry inputs the execution result of the substrate processing, the sensor data of the temperature, and the film formation time into the second model of the simulation model, and calculates the temperature of the heater of the substrate processing apparatus and the film formation time that are predicted to approach the target value for the substrate processing result, and
the optimization circuitry optimizes the process parameter based on the calculated opening degree of the pressure control valve, the calculated temperature of the heater, and the calculated film formation time.

5. The information processing apparatus according to claim 4, wherein the substrate processing is film formation processing using an ALD method in which one cycle of a process including supplying a raw material gas and supplying a reactant gas is repeated for a film formation count set in advance, and
the optimization circuitry optimizes the film formation count to be used as the film formation time.

6. The information processing apparatus according to claim 5, further comprising:
a display control circuitry configured to display the predicted value of the substrate processing result on a display.

7. The information processing apparatus according to claim 6, wherein the optimization circuitry updates the process parameter to be used in the substrate processing apparatus with an optimized process parameter in accordance with an instruction from a user for the predicted value of the substrate processing result displayed on the display.

8. The information processing apparatus according to claim 6, wherein the optimization circuitry automatically determines whether or not to update the process parameter to be used in the substrate processing apparatus with the optimized process parameter based on the predicted value of the substrate processing result being displayed.

9. The information processing apparatus according to claim 2, wherein the substrate processing apparatus processes a plurality of substrates simultaneously by inserting a substrate holding portion configured to hold the substrates into the substrate processing apparatus,
the data acquisition circuitry acquires execution result data including an execution result of processing for the plurality of substrates based on the process parameter, the opening degree of the pressure control valve, and the temperature of the substrate processing apparatus, and
the execution result of the substrate processing includes a value indicating in-plane uniformity of film thickness on the substrate formed by the substrate processing and inter-plane uniformity of film thickness between the plurality of substrates.

10. A non-transitory computer-readable storage medium having stored therein a parameter control program that causes a computer to execute a process comprising:
acquiring execution result data including an execution result of a substrate processing based on a process parameter including a pressure in a substrate processing apparatus, and including sensor data of the pressure in the substrate processing apparatus;
inputting the execution result data into a simulation model stored in a storage to calculate a pressure in the substrate processing apparatus that is predicted to approach a target value for a substrate processing result; and
calculating a predicted value of the substrate processing result based on the process parameter including the calculated pressure.
